(19) United States
(12) Patent Application Publication
(10) Pub. No.: US 2013/0054163 A1
(43) Pub. Date: Feb. 28, 2013

(54) POWER MEASURING SYSTEM

(71) Applicants: QI-YAN LUO, Shenzhen City (CN); SONG-LIN TONG, Shenzhen City (CN); YI-XIN TU, Shenzhen City (CN); HAI-QING ZHOU, Shenzhen City (CN)

(72) Inventors: QI-YAN LUO, Shenzhen City (CN); SONG-LIN TONG, Shenzhen City (CN); YI-XIN TU, Shenzhen City (CN); HAI-QING ZHOU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/305,060

(22) Filed: Nov. 28, 2011

(30) Foreign Application Priority Data
Aug. 25, 2011 (CN) 201110245851.9

(51) Int. Cl. G01R 21/00; G06F 19/00

(52) U.S. Cl. 702/60

(57) ABSTRACT

A power measuring system for measuring a turning-on power, a turning-off power, and a turned-on power of a first field-effect transistor includes a pulse driver, a first resistor, a processing unit, and an indication unit. The pulse driver generates square wave signals. The processing unit samples voltages at the source and the drain of the first field-effect transistor, and at the first and second terminals of the first resistor at the moment when the square wave signals changes from low to high or from high to low, and calculates the turning-on power, the turning-off power, and the turned-on power of the first field-effect transistor. The indication unit displays the turning-on power, the turning-off power, and the turned-on power of the first field-effect transistor.

### BACKGROUND

1. Technical Field

The present disclosure relates to a power measuring system.

2. Description of Related Art

To measure a turning-on power, a turning-off power, and a turned-on power of a field-effect transistor, a specific device may be used, but this is not cost effective. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIGS. 1 and 2 are circuit diagrams of an exemplary embodiment of a power measuring system, wherein the power measuring system includes a pulse driver.

FIG. 3 is a graph of the wave output from the pulse driver of FIG. 2.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

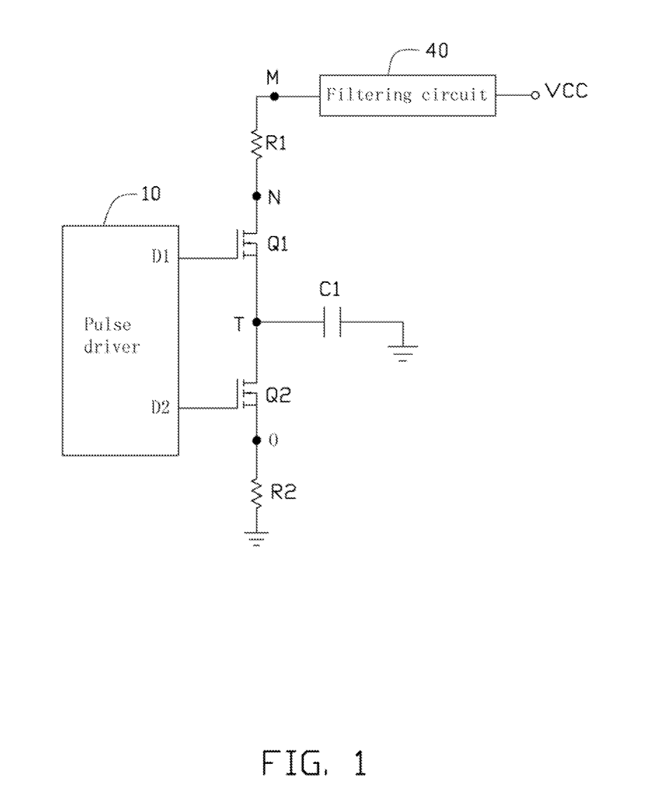

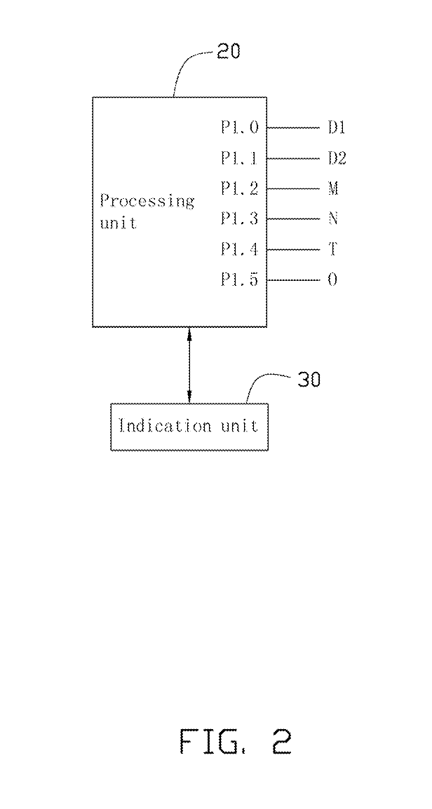

Referring to FIGS. 1 and 2, an exemplary embodiment of a power measuring system includes a pulse driver 10, a processing unit 20, an indication unit 30, a filtering circuit 40, a capacitor C1, two field-effect transistors (FETs) Q1 and Q2, and two resistors R1 and R2.

The pulse driver 10 generates square-wave signals. The pulse driver 10 includes two pins D1 and D2. The pin D1 outputs square-wave signals to a gate of the FET Q1. The pin D2 outputs square-wave signals to a gate of the FET Q2. A drain of the FET Q1 is connected to a power supply VCC through the resistor R1 and the filtering circuit 40, in that order. A source of the FET Q1 and a drain of the FET Q2 are connected to each other and to the capacitor C1. A source of the FET Q2 is grounded through the resistor R2. The capacitor C1 is further grounded.

The processing unit 20 includes six pins P1.0-P1.5. The pin P1.0 is connected to the pin D1 of the pulse driver 10. The pin P1.1 is connected to the pin D2 of the pulse driver 10. The pin P1.2 is connected to a node M between the resistor R1 and the filtering circuit 40. The pin P1.3 is connected to a node N between the resistor R1 and the drain of the FET Q1. The pin P1.4 is connected to a node T between the drain of the FET Q2 and the source of the FET Q1. The pin P1.5 is connected to a node O between the source of the FET Q2 and the resistor R2. The processing unit 20 is further connected to the indication unit 30.

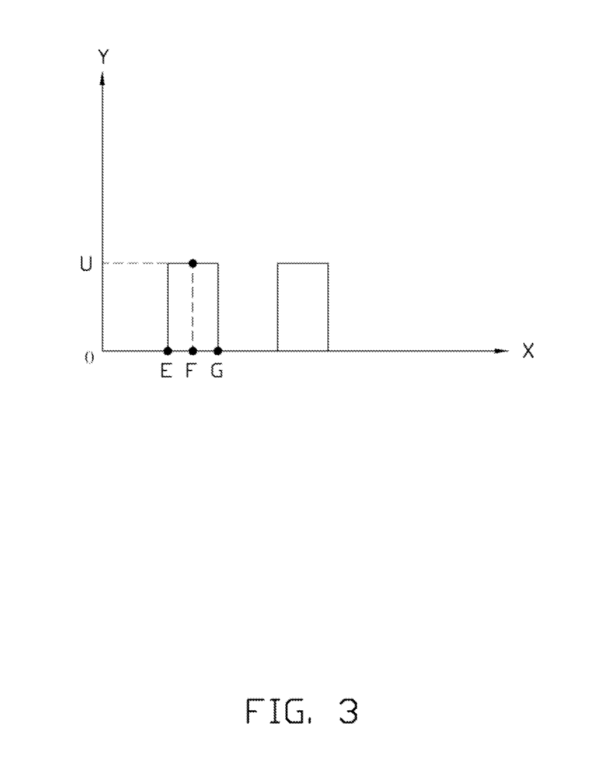

Referring to FIG. 3, the graph of a square-wave is shown. In FIG. 3, the X axis denotes time, and the Y axis denotes voltage. At the point E, namely at the moment when the square wave signal is changing from a low level to a high level, the FETs Q1 and Q2 are turning on. At this time, the product of the voltage and current supplied to the FETs Q1 and Q2 is called a turning-on power. At the point G, namely at the moment when the square wave signal is changing from a high level to a low level, the FETs Q1 and Q2 are turning off. At this time, the product of the voltage and the current supplied to the FETs Q1 and Q2 is called a turning-off power. According to the character of the particular FET, the turning-on power of the FET is equal to the turning-off power, such that, in this embodiment, the turning-on power and the turning-off power are called a first power. At the point F, the square wave signal is at a high level, and both the FETs Q1 and Q2 are turned on. At this time, the power of the FETs Q1 and Q2 is called a turned-on power. In this embodiment, the turned-on power is regarded as a second power.

The processing unit 20 samples voltages at the nodes M, N, T, and O at the time points E and F. The processing unit 20 further obtains the voltage drop Vr1 across the two terminals of the resistor R1, the voltage drop Vr2 between the two terminals of the resistor R2, the voltage drop Vq1 between the drain and the source of the FET Q1, and the voltage drop Vq2 between the drain and the source of the FET Q2. A current Ir1 is obtained from the voltage drop Vr1 divided by the resistance of the resistor R1. The current Ir1 is equal to a current flowing through the FET Q1 and a current flowing through the FET Q2. As a result, according to the formula P=VI, the first and second powers of the FETs Q1 and Q2 can be obtained. In the formula P=VI, P denotes power, V denotes the voltage, and I denotes the current. In addition, from information described above, the current flowing through the FET Q1 is equal to the current flowing through the FET Q2. As a result, the processing unit 20 just needs to obtain one of the voltage drop Vr1 and Vr2.

After the first and second powers of the FETs Q1 and Q2 are obtained, the processing unit 20 transmits the power values of the first and second powers to the indication unit 30. The indication unit 30 displays the first and second powers.

In other embodiments, the power measuring system can measure the first and second powers of one FET Q1 only. In this case, the source of the FET Q1 is grounded. The processing unit 20 samples voltages at the nodes M, N, and T at the time points E and F. In a similar manner as above, the first and second powers of a single FET Q1 can be obtained.

In this embodiment, the filtering circuit 40 and the capacitor C1 are used for stabilizing the current from the power supply VCC.

The foregoing description of the exemplary embodiments of the disclosure has been presented only for the purposes of illustration and description and is not intended to be exhaustive or to limit the disclosure to the precise forms disclosed. Many modifications and variations are possible in the light of everything above. The embodiments were chosen and described in order to explain the principles of the disclosure and their practical application so as to enable others of ordinary skill in the art to utilize the disclosure and various embodiments with various modifications as are suited to the particular use contemplated. Alternative embodiments will become apparent to those of ordinary skills in the art to which the present disclosure pertains without departing from its spirit and scope. Accordingly, the scope of the present disclosure is defined by the appended claims rather than the foregoing description and the exemplary embodiments described therein.

What is claimed is:

1. A power measuring system for measuring a turning-on power, a turning-off power, and a turned-on power of a first field-effect transistor, the power measuring system comprising:
a pulse driver to generate square wave signals, wherein the pulse driver comprises a first pin, a gate of the first field-effect transistor is connected to the first pin of the pulse driver, a source of the first field-effect transistor is grounded;
a first resistor, wherein a drain of the first field-effect transistor is connected to a power supply through the first resistor;
a processing unit comprising a first pin connected to the source of the first field-effect transistor, a second pin connected to the drain of the first field-effect transistor, a third pin connected to the first pin of the pulse driver, a fourth pin connected to a node between the first resistor and the power supply, wherein the processing unit samples voltages at the source, the drain of the first field-effect transistor, and two terminals of the first resistor at the moment when a level of the square wave signals changes, and calculates the turning-on power, the turning-off power, and the turned-on power of the first field-effect transistor; and
an indication unit connected to the processing unit to display the turning-on power, the turning-off power, and the turned-on power of the first field-effect transistor.

2. The power measuring system of claim 1, further comprising a filtering circuit connected between the first resistor and the power supply.

3. The power measuring system of claim 1, further comprising a capacitor connected to the source of the first field-effect transistor.

4. The power measuring system of claim 1, wherein the processing unit calculates a voltage drop across two terminals of the first resistor according to the voltages at the two terminals of the first resistor, and a current flowing through the first resistor at the moment when a level of the square wave signals changes, the turning-on power and the turning-off power of the first filed-effect transistor equal to a product of a voltage drop between the drain and the source of the first field-effect transistor and the current flowing through the first resistor.

5. The power measuring system of claim 1, wherein the processing unit calculates a voltage drop across two terminals of the first resistor according to the voltages at the two terminals of the first resistor, and a current flowing through the first resistor when the square wave signals are at a high level, the turned-on power of the first filed-effect transistor equals to a product of a voltage drop between the voltages at the drain and the source of the first field-effect transistor and the current flowing through the first resistor.

6. A power measuring system for measuring turning-on powers, turning-off powers, and turned-on powers of first and second field-effect transistors, the power measuring system comprising:
a pulse driver to generate square wave signals, wherein the pulse driver comprises a first pin and a second pin, a gate of the first field-effect transistor is connected to the first pin of the pulse driver, a gate of the second field-effect transistor is connected to the second pin of the pulse driver, a source of the first field-effect transistor is connected to a drain of the second field-effect transistor;
a first resistor, wherein a drain of the first field-effect transistor is connected to a power supply through the first resistor;
a second resistor, wherein a source of the second field-effect transistor is grounded through the second resistor;
a processing unit comprising a first pin connected to the source of the first field-effect transistor, a second pin connected to the drain of the first field-effect transistor, a third pin connected to the first pin of the pulse driver, a fourth pin connected to a node between the first resistor and the power supply, a fifth pin connected to a second pin of the pulse driver, a sixth pin connected to a node between the source of the second field-effect transistor and the second resistor, wherein the processing unit samples voltages at the source, the drain of the first and second field-effect transistors, and two terminals of the first and second resistors at the moment when a level of the square wave signals changes, and calculates the turning-on powers, the turning-off powers, and the turned-on powers of the first and second field-effect transistors; and
an indication unit connected to the processing unit to display the turning-on powers, the turning-off powers, and the turned-on powers of the first and second field-effect transistors.

7. The power measuring system of claim 6, further comprising a filtering circuit connected between the first resistor and the power supply.

8. The power measuring system of claim 6, further comprising a capacitor connected to the source of the first field-effect transistor.

9. The power measuring system of claim 6, wherein the processing unit calculates a voltage drop across two terminals of the first resistor according to the voltages at the two terminals of the first resistor, and a current flowing through the first resistor at the moment when a level of the square wave signals changes, the turning-on power and the turning-off power of the first filed-effect transistor equal to a product of a voltage drop between the voltages at the drain and the source of the first field-effect transistor and the current flowing through the first resistor.

10. The power measuring system of claim 9, wherein the processing unit further calculates a voltage drop between the voltages at the drain and the source of the second field-effect transistor, the turning-on power and the turning-off power of the second filed-effect transistor equal to a product of the voltage drop between the voltages at the drain and the source of the second field-effect transistor and the current flowing through the first resistor.

11. The power measuring system of claim 6, wherein the processing unit calculates a voltage drop across two terminals of the first resistor according to the voltages at the two terminals of the first resistor, and a current flowing through the first resistor when the square wave signals are at a high level, the turned-on power of the first filed-effect transistor equals to a product of a voltage drop between the voltages at the drain and the source of the first field-effect transistor and the current flowing through the first resistor.

12. The power measuring system of claim 11, wherein the processing unit calculates a voltage drop between the voltages at the drain and the source of the second field-effect transistor when the square wave signals are at a high level, the turned-on power of the second filed-effect transistor equals to a product of a voltage drop between the voltages at the drain and the source of the second field-effect transistor and the current flowing through the first resistor.
